(19) United States
(12) Patent Application Publication
(10) Pub. No.: US 2017/0236769 A1
(43) Pub. Date: Aug. 17, 2017

(54) HIGH THERMAL CONDUCTIVE HERMETIC RF PACKAGING

(71) Applicant: Thermal Management Solutions, LLC d/b/a SANTIER, San Diego, CA (US)

(72) Inventors: Sanchayan DUTTA, Escondido, CA (US); Kevin COTNER, Fallbrook, CA (US)

(21) Appl. No.: 15/430,630

(22) Filed: Feb. 13, 2017

Related U.S. Application Data
(60) Provisional application No. 62/294,049, filed on Feb. 11, 2016.

(51) Int. Cl. H01L 23/373

(52) U.S. Cl. CPC H01L 23/3735; H01L 23/3736; H01L 23/3731

(57) ABSTRACT

A thermal packaging device for dissipating heat generated by electronic components comprising a copper base and a ceramic frame mounted to the base with a buffer comprising a nickel-cobalt ferrous alloy. Also disclosed is a thermal packaging device with a base comprised of a layer of copper molybdenum alloy sandwiched between two layers of copper and a ceramic frame mounted to the base. Further disclosed is a thermal packaging device with a base comprised of alternating layers of copper, molybdenum, and copper; and a ceramic frame mounted to the base.

### CROSS-REFERENCE TO RELATED APPLICATIONS

This application claims priority to provisional application 62/294,049, filed Feb. 11, 2016.

### FIELD OF THE INVENTION

The invention relates to the field of packaging semiconductor devices. In particular, the invention relates to the field of hermetic, non-organic packaging of high power and/or high frequency semiconductor devices. More particularly, the invention relates to hermetic and non-hermetic packages that are closely matched to the coefficient of thermal expansion of the semiconductor/Laser devices mounted thereupon and that provide a thermally conductive pathway for heat dissipation.

### BACKGROUND OF THE INVENTION

Much of the semiconductor packaging currently in use in the electronics industry is produced from organic laminate materials; however, there still exists a need for hermetic and non hermetic, non-organic-based packaging for high power, high operating temperature, and high frequency semiconductor, as well as laser, applications where extremely high heat is generated by semiconductor and laser devices.

In operation, many of the semiconductor applications that require hermetic packaging generate significant amounts of heat that must be dissipated to maintain optimum functionality and reliability of the device. In these applications, at least a base plate of the semiconductor package is desirably formed from a thermally conductive material or structure. The efficiency with which the thermally conductive base plate can conduct waste heat away from the operating device is dependent on the thermal pathway between the semiconductor and the base plate. The most thermally efficient pathway is when the device is directly mounted onto the base plate with a continuous interface. Directly mounting the semiconductor/laser device to the base plate results in the two elements becoming mechanically coupled. If the coefficient of thermal expansion of the semiconductor/laser device and the base plate are significantly different, the mechanical integrity of the semiconductor device may be compromised. Therefore, it is important that the thermal coefficient of expansion (CTE) of the thermally conductive baseplate be generally matched to the semiconductor device.

### SUMMARY OF THE INVENTION

The microelectronics power packaging for RF applications needs several unique features, including: 1) efficient heat sinking; 2) relatively light weight materials; 3) robust construction for high reliability in harsh environment conditions; 4) low inductance while carrying high current from inside to outside of the package or vice versa; 5) High thermal conductive base with a high CTE but hermetic sealing; 6) minimal parasitic oscillations; and 7) low cost of fabrication.

One preferred embodiment comprises an alumina (ceramic) ring frame attached to the copper base material with the use of a nickel-cobalt ferrous alloy buffer between the ceramic ring frame and the copper base.

A second preferred embodiment uses a base plate made from a laminate of CPC, comprising a layer of copper molybdenum alloy having a composition of about 70:30 or 50:50 sandwiched between two thickness of copper, to match the CTE of the alumina ceramic frame.

In another embodiment, which can also be used in applications where hermeticity is required, the base plate is made of S-CMC, which comprises alternating layers of copper, molybdenum, and copper in odd-numbers of laminates, such as 3, 5, 7 or nine layers. In this configuration, the CTE of the base can be adjusted to match even the CTE of the highest CTE substrates, such as gallium nitride.

### BRIEF DESCRIPTION OF THE DRAWINGS

FIG. 1 is an illustration of the top view of one embodiment of the present invention, including sectional views A-A and B-B.

FIG. 2 is an illustration of the perspective view of one embodiment of the present invention.

FIG. 3 is an illustration of the top view of a second embodiment of the present invention, including sectional views A-A and B-B.

FIG. 4 is an illustration of the perspective view of a second embodiment of the present invention.

FIG. 5 is an illustration of the top view of another embodiment of the present invention.

FIG. 6 is an illustration of the side view of another embodiment of the present invention.

FIG. 7 is an illustration of another side view of another embodiment of the present invention.

### DETAILED DESCRIPTION OF THE INVENTION

One preferred embodiment comprises a two-lead configuration with dimensions of approximately 0.400×0.400×0.080 inches for an RF power package design. The design uses a copper base plate 12 that is nickel plated to provide maximum signal integrity around the signal carrying leads 16 without encountering parasitic oscillations at high frequency signals. The chip or die to be mounted in the package may be a high power and heat generating GaN compound semiconductor material.

This preferred embodiment comprises a mechanical attachment using a high reliability brazing process which allows the attachment of the alumina (ceramic) ring frame 14 onto the copper base material 12 with the use of a nickel-cobalt ferrous alloy (such as Kovar®) buffer 10 between the ceramic ring frame 14 and the copper base 12. Kovar® is a commercially available nickel-cobalt ferrous alloy compositionally identical to Fernico 1, designed to have substantially the same thermal expansion characteristics as borosilicate glass (˜5×10-6/K between 30 and 200° C., to ˜10×10-6/K at 800° C.).

This Kovar® buffer 10 improves the performance of the package substantially without the cost of manufacturing often encountered using CuDiamond, Graphene and SiC base materials in combination with other base materials to achieve higher thermal conductivity with matched CTE with the die in use. Commercial applications for the internet of things will require lower costs and wider bandwidth in RF components. For example, a GaN compound semiconductor material on a SiC [window frame] was able to be attached to a copper base plate directly with a pliable thermal interface material, such as nano-sized silver particles infused into an epoxy adhesive.

This Kovar® interface material 10 eliminates the need for an exact match of the CTE between the copper base flange and the semiconductor die 18.

This configuration is able to provide a compatible fully hermetic package design. The thermal packaging device thus, in essence, comprises a copper base plate 12 that is thermal conductive in all three axes in excess of 350 Wm/K; and a ceramic window frame attached to the copper base plate with a Kovar buffer to mitigate the CTE mismatch between the alumina ceramic at 7 ppm and copper at 16.4 ppm, thus preventing cracks in the ceramic 14. The thermal packaging device 8 is fully hermetic so as to pass reliability testing for the application.

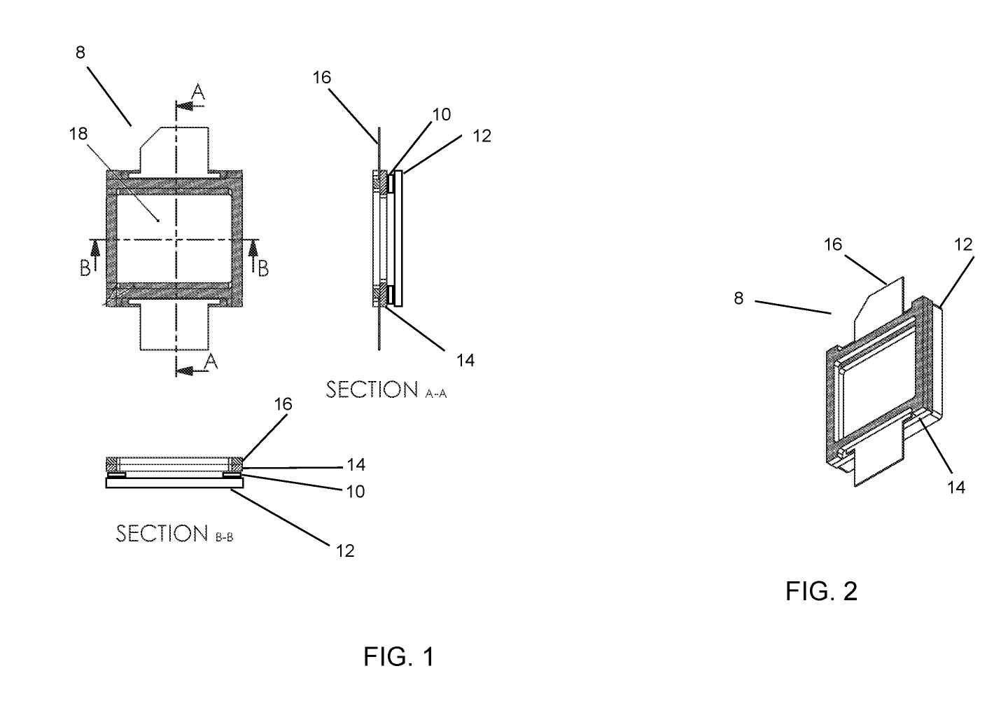

As shown in FIGS. 1 and 2, the thermal packaging device 8 uses a Kovar buffer 10 to mitigate the CTE mismatch between the copper base material 12 and the surrounding alumina (ceramic) window frame 14 to package the GaN die 18 in lead frame 16.

The ceramic material is preferably a multi-layered ceramic metal oxide, such as alumina, which is screenprinted with a refractory metal, such as tungsten, on the layers to create circuits on the ceramic interlayers before the layers first joined by lamination. The wafer layers of the ceramic frame 14 are then co-fired to a high temperature of approximately 1500° C.

The ceramic frame 14 is nickel plated and then brazed to the Kovar buffer 10, forming a subassembly. This subassembly is then nickel plated, and finally gold plated, in preparation for being gold-tin soldered to the copper base plate 12.

The copper base plate 12 is plated with a layer of nickel, and then a layer of gold, and finally soldered with gold-tin solder to the ceramic frame 14 and Kovar buffer 10 subassembly, for mounting to the lead frame 16.

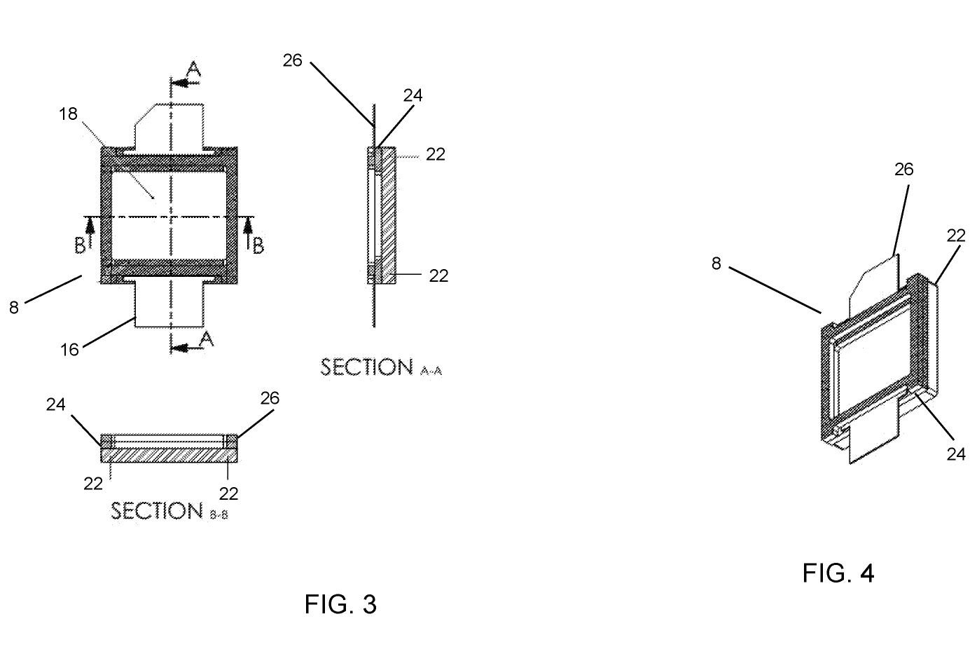

A second preferred embodiment can be used in applications where hermeticity is required. As shown in FIGS. 3 and 4, the thermal packaging device 8 uses a base plate 22, made from a laminate of CPC, comprising a layer of copper molybdenum alloy having a composition of about 70:30 sandwiched between two thickness of copper, to match the CTE of the alumina ceramic frame 24. The layer of copper molybdenum alloy 30 preferably has a thickness of approximately four times that of the copper layers. By using an appropriate thickness (approximately 100 micro inches) of nickel plating on this CPC base plate 22, it can be made highly hermetic and can be brazed to the alumina ceramic material of the window frame 24 using copper silver brazing. Then, the entire assembly can be flash plated with nickel, followed by a gold plating to produce a heat sink with a high thermal conductivity, along with high hermetic capability. The alumina (ceramic) window frame 24 can then be used to package the GaN die 18 in lead frame 26.

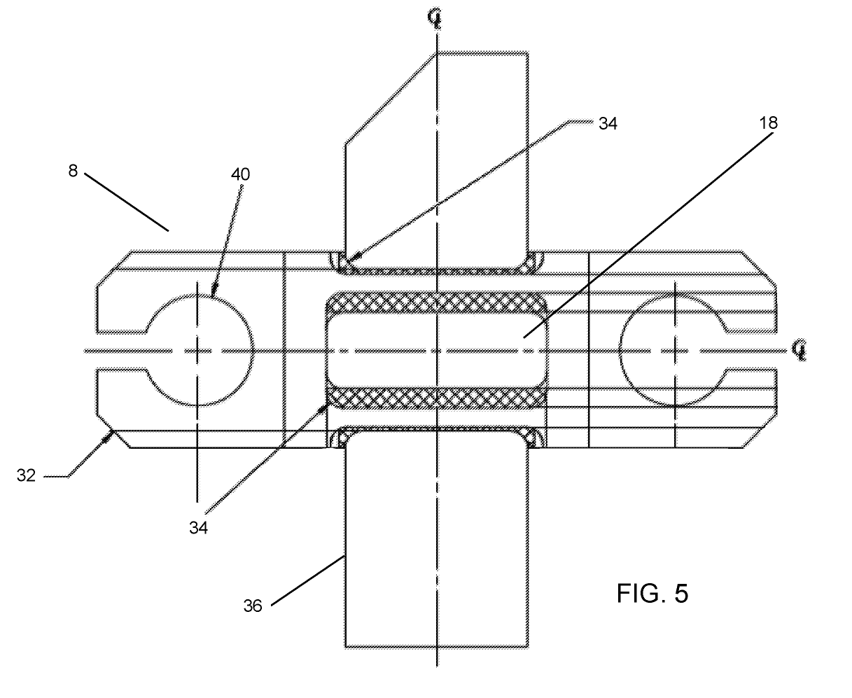

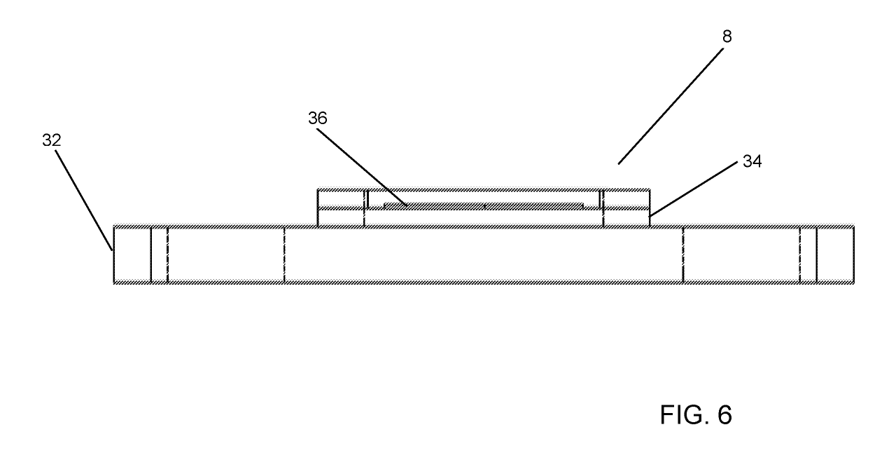

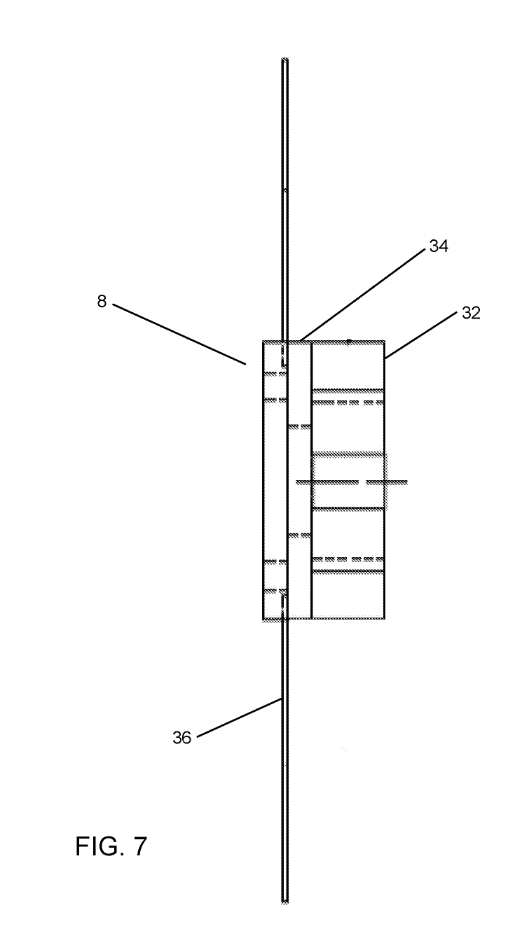

In another embodiment, which can also be used in applications where hermeticity is required, the base plate 32 is made of S-CMC, which comprises alternating layers of copper, molybdenum, and copper in odd-numbers of laminates, such as 3, 5, 7 or nine layers. In this configuration, the CTE of the base can be adjusted to match even the CTE of the highest CTE substrates, such as gallium nitride. As shown in FIGS. 5-7, the thermal packaging device 8 uses an S-CMC laminate flange base 32, with an opening 40 to accommodate a fastener for mounting. Flange base 32 is first annealed and then plated with nickel up to approximately 100 micro inches for hermeticity, and then is brazed to the alumina ceramic material of the window frame 34 using copper silver brazing. Then, the entire assembly can be flash plated with nickel, followed by a gold plating to produce a heat sink with a high thermal conductivity, along with high hermetic capability. The alumina (ceramic) window frame 34 can then be used to package the GaN die 18 in lead frame 36.

We claim:

1. A thermal packaging device comprising:
a copper base;
a ceramic frame mounted to the base with a buffer comprising a nickel-cobalt ferrous alloy.

2. The thermal packaging device of claim 1 wherein the ceramic frame comprises a multi-layered co-fired ceramic metal oxide.

3. The thermal packaging device of claim 1 wherein the ceramic frame is nickel plated and brazed to the buffer.

4. The thermal packaging device of claim 3 wherein the ceramic frame and buffer are nickel plated and gold plated.

5. The thermal packaging device of claim 1 wherein the copper base is plated with a layer of nickel, and then a layer of gold, and soldered with gold-tin solder to the ceramic frame and buffer.

6. A thermal packaging device comprising:
a base comprised of a layer of copper molybdenum alloy sandwiched
between two layers of copper; and
a ceramic frame mounted to the base.

7. The thermal packaging device of claim 6 wherein the ceramic frame comprises a multi-layered co-fired ceramic metal oxide.

8. The thermal packaging device of claim 6 wherein the base is brazed to the ceramic frame using copper silver brazing.

9. The thermal packaging device of claim 8 wherein the ceramic frame and base are nickel plated and gold plated.

10. The thermal packaging device of claim 6 wherein the base is plated with a layer of nickel prior to brazing to the ceramic frame.

11. The thermal packaging device of claim 10 wherein the thickness of the nickel plating is approximately 100 microinches.

12. The thermal packaging device of claim 6 wherein the copper molybdenum alloy has a composition of about 70:30.

13. The thermal packaging device of claim 6 wherein the layer of copper molybdenum alloy has a thickness of approximately four times that of the copper layers.

14. A thermal packaging device comprising:
a base comprised of alternating layers of copper, molybdenum, and copper; and
a ceramic frame mounted to the base.

15. The thermal packaging device of claim 14 wherein the ceramic frame comprises a multi-layered co-fired ceramic metal oxide.

16. The thermal packaging device of claim 14 wherein the base is brazed to the ceramic frame using copper silver brazing.

17. The thermal packaging device of claim 16 wherein the base is annealed and plated with a layer of nickel prior to brazing to the ceramic frame.

18. The thermal packaging device of claim 17 wherein the thickness of the nickel plating is approximately 100 microinches.

19. The thermal packaging device of claim 14 wherein the ceramic frame and base are nickel plated and gold plated.
